(19) United States
(12) Patent Application Publication
(10) Pub. No.: US 2011/0063066 A1
(43) Pub. Date: Mar. 17, 2011

(54) SPACE TRANSFORMER FOR PROBE CARD AND METHOD OF REPAIRING SPACE TRANSFORMER

(75) Inventors: Yong Seok CHOI, Suwon (KR); Yun Hwi Park, Yongin (KR); Won Chul Ma, Suwon (KR); Kuk Hyun Kim, Suwon (KR); Kwang Jin Ha, Suwon (KR)

(73) Assignee: SAMSUNG ELECTRO-MECHANICS CO., LTD.

(21) Appl. No.: 12/642,060

(22) Filed: Dec. 18, 2009

(30) Foreign Application Priority Data
Sep. 17, 2009 (KR) 10-2009-0088107

(51) Int. Cl. H01F 27/28; H01F 41/04

(52) U.S. Cl. 336/200; 29/602.1

(57) ABSTRACT

A space transformer for a probe card includes: a multilayered circuit board having first and second faces which face each other and a plurality of side faces connecting the first and second faces; a plurality of channels including a first pad formed on the first face and receiving an electrical signal applied from the exterior, a second pad formed on the second face, to which a probe is connected, and a through wiring penetrating the multilayered circuit board and connecting the first and second pads; and side wirings formed on the side faces and connecting first and second pads of a damaged channel among a plurality of channels. When a portion of channels transferring an electrical signal to probes is damaged, the space transformer can repair the damaged channel by means of the side wirings.

### CROSS-REFERENCE TO RELATED APPLICATIONS

This application claims the priority of Korean Patent Application No. 10-2009-0088107 filed on Sep. 17, 2009, in the Korean Intellectual Property Office, the disclosure of which is incorporated herein by reference.

### BACKGROUND OF THE INVENTION

1. Field of the Invention

The present invention relates to a space transformer for a probe card and a method of repairing the space transformer and, more particularly, to a space transformer for a probe card capable of repairing a damaged channel and a method of repairing the space transformer.

2. Description of the Related Art

In general, a semiconductor device is fabricated through a fabrication process in which a circuit pattern and a contact pad for inspection are formed on a wafer and an assembly process in which the wafer with the circuit pattern and the contact pad formed thereupon is divided into individual semiconductor chips.

Between the fabrication process and the assembly process, an inspection process is performed to check the electrical characteristics of the wafer by applying an electrical signal to the contact pad formed on the wafer.

The inspection process is performed in order to determine whether or not the wafer is defective, so as to remove a defective portion of the wafer during the assembly process.

During the inspection process, a piece of inspection equipment generally known as a tester, that applies the electrical signal to the wafer, and another piece of inspection equipment generally known as a probe card, that performs an interface function between the wafer and the tester, are commonly used.

The probe card includes a plurality of probes brought into contact with the contact pad formed on the wafer and a printed circuit board (PCB) which receive the electrical signal applied from the tester and the contact pad formed on the wafer.

Recently, as the demand for a high-integrated chip has increased, the circuit pattern formed on the wafer through the fabrication process and the contact pad connected with the circuit pattern on the wafer have become highly integrated. Namely, the space between neighboring contact pads is extremely narrow and the size of the contact pads themselves is extremely small. In line with this, the probes of the probe card used for the inspection process must be formed to have an extremely narrow space therebetween to correspond to the contact pads so as to come into contact with the contact pads and must have an extremely small size.

In order to inspect the contact pads having such fine pitches, the probes of the probe card are also to be formed to have fine pitches, for which a space transformer is used between the PCB and the probes in order to compensate for the difference between the space between the terminals on the PCB and the space between probes.

The space transformer includes a plurality of channels for applying an electrical signal to the probes, and the number of channels of the space transformer increases according to the trend of high integration of the wafer chips.

The space transformer is one of the most high-priced components constituting the probe card. Thus, if a portion of the channels transferring signals to the probe is defective (e.g., aging of signal lines, etc.) the space transformer itself cannot be used and must be replaced by a new one.

### SUMMARY OF THE INVENTION

An aspect of the present invention provides a space transformer for a probe card capable of repairing a damaged channel, and a method of repairing the space transformer.

According to an aspect of the present invention, there is provided a space transformer for a probe card, including: a multilayered circuit board having first and second faces which face each other and a plurality of side faces connecting the first and second faces; a plurality of channels including a first pad formed on the first face and receiving an electrical signal applied from the exterior, a second pad formed on the second face, to which a probe is connected, and a through wiring penetrating the multilayered circuit board and connecting the first and second pads; and side wirings formed on the side faces and connecting first and second pads of a damaged channel among a plurality of channels.

The side wirings may be formed on every side faces of the multilayered circuit board.

The damaged channel may be connected by a side wiring formed to be nearest among the side wirings.

The side wirings may include a first conductive line formed on the side of the multilayered circuit board, a second conductive line connecting the first conductive line and the first pad, and a third conductive line connecting the first conductive line and the second pad.

The second and third conductive lines may be formed at the shortest distance.

The side wirings may be made of one selected from the group consisting of copper, gold, tungsten, sliver, and alloys thereof.

According to another aspect of the present invention, there is provided a method of repairing a space transformer for a probe card, including: preparing a multilayered circuit board having first and second faces which face each other and a plurality of side faces connecting the first and second faces; forming a plurality of channels including a first pad formed on the first face and receiving an electrical signal applied from the exterior, a second pad formed on the second face, to which a probe is connected, and a through wiring penetrating the multilayered circuit board and connecting the first and second pads; and forming side wirings on the side faces to connect first and second pads of a damaged channel among a plurality of channels.

The side wirings may include a first conductive line formed on the side of the multilayered circuit board, a second conductive line connecting the first conductive line and the first pad of the damaged channel, and a third conductive line connecting the first conductive line and the second pad of the damaged channel, wherein the first conductive line is fired along with the multilayered circuit board.

The first conductive line, the second conductive line, and the third conductive line may be formed after the multilayered circuit board is fired.

The first conductive line, the second conductive line, and the third conductive line may be formed through screen printing, thin film sputtering, or aerosol deposition.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic view of a probe card including a space transformer according to an exemplary embodiment of the present invention;

FIG. 2 is a schematic perspective view of the space transformer according to an exemplary embodiment of the present invention;

FIG. 3 is a sectional view showing a portion of the space transformer taken along line A-A′ in FIG. 2; and

FIGS. 4a and 4b are sectional views for explaining a method for repairing a damaged channel by the space transformer according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, shapes and dimensions may be exaggerated for clarity, and the same reference numerals will be used throughout to designate the same or like components.

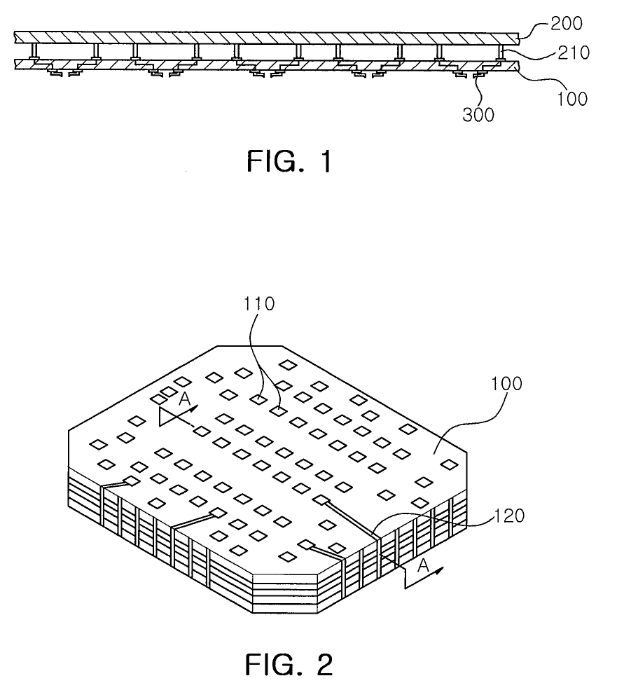

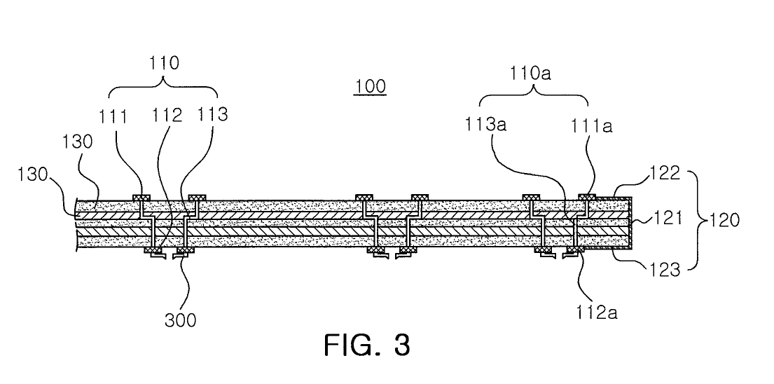

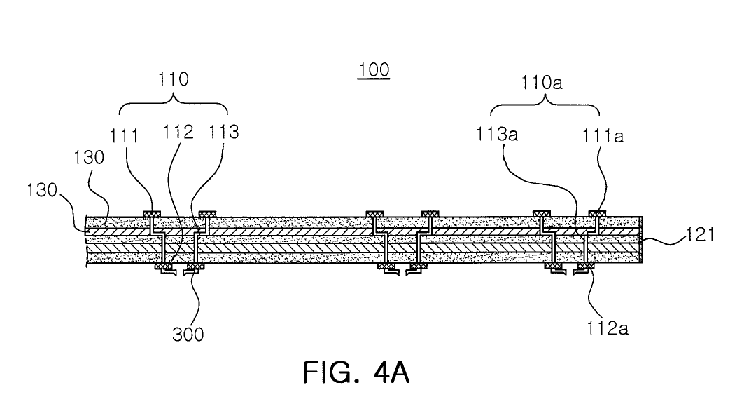

FIG. 1 is a schematic view of a probe card including a space transformer according to an exemplary embodiment of the present invention. FIG. 2 is a schematic perspective view of the space transformer according to an exemplary embodiment of the present invention. FIG. 3 is a sectional view showing a portion of the space transformer taken along line A-A′ in FIG. 2.

With reference to FIG. 1, a probe card includes a printed circuit board (PCB) 200, an interposer 210, a space transformer 100, and probes 300.

The PCB 200 may have a disk-like shape having upper and lower surfaces. A probe circuit pattern (not shown) for an inspection process is formed on the upper surface of the PCB 200, and a groove may be formed between neighboring probe circuit patterns. A hole is formed on a lower surface of the PCB 200, and the interpose 210 may be mounted in the hole.

Because a probe card inspects highly integrated wafer, the space between neighboring probe circuit patterns formed on the upper surface of the PCB 200 is prone to be extremely narrow and interference may be generated between the neighboring probe circuit patterns by current leaking into a neighboring probe circuit pattern. The groove formed between the probe circuit patterns serves to restrain interference between probe circuit patterns due to current leakage.

In addition, a pitch conversion may be performed through wiring penetrating from the upper surface to the lower surface of the PCB in order to inspect the high-integrated wafer. The PCB 200 may be connected to a tester (not shown) for an inspection process.

The interposer 120 is positioned in a space between the PCB 200 and the space transformer 100. One end of the interposer 120 is connected with the probe circuit pattern of the PCB 200 and the other end of the interposer 120 is in contact with the space transformer 100. In detail, the other end of the interposer 120 is in contact with a first pad of a channel formed at the space transformer 100

The interposer 210 serves to transfer an electrical signal which has passed through the PCB 200 for an inspection process to the space transformer 100.

The interposer 210 is an interface unit for electrically connecting the PCB 200 and the space transformer 100, and may have various shapes.

With reference to FIGS. 2 and 3, the space transformer 100 may be comprised of a multilayered circuit board 130, and include a plurality of channels 110 electrically connected with the interposer 210 and side wirings 120.

The multilayered circuit board 130 is an insulation substrate including ceramic, glass, silicon, etc., and has first and second faces that face each other, and a plurality of side faces connecting the first and second faces.

The first face faces the PCB 200, and the plurality of probes 300, which are in direct contact with an inspection target (wafer chip), are connected to the second face.

The plurality of channels 110 are formed on the first face of the multilayered circuit board, and include a first pad 111 connected with another end of the interposer 210, a second pad 112 formed on the second face of the multilayered circuit board and electrically connected with the probes 300, and a through wiring 113 penetrating the multilayered circuit board and connecting the first and second pads 111 and 112.

The space transformer 100 transfers an electrical signal received from the PCB 200 to the probes 300 by means of the plurality of channels 110.

The side wiring 120 is formed on the side of the multilayered circuit board and connected with a damaged channel 113a among the plurality of channels.

In order to transfer an electrical signal received from the PCB 200 to the probes 300, the space transformer 100 has the plurality of channels 110 formed in the interior of the multilayered circuit board 130. The plurality of channels 110 include the first and second pads 111 and 112 formed on the first and second faces, respectively, and the through wirings 113 electrically connecting the first and second pads 111 and 112.

The through wirings 113 are formed through a via hole formation and via fill process when the multilayered circuit board is fabricated and stacked. However, in the complicated via electrode formation process, a short circuit may be generated by the through wiring 113. Also, recently, as the size of the space transformer has increased, the likelihood of short circuits generated by the through wirings increases. In addition, the through wirings may be defective during their formation process or may become defective for the wafer chip inspection process.

When a short circuit is generated from some of the through wirings, the overall space transformer is defective, so the high-priced space transformer cannot be used.

In the present exemplary embodiment, even if some through wirings are short-circuited, the space transformer can be repaired by means of the side wirings.

In a state wherein the plurality of channels 110 are formed, if the through wiring 113a is found to have a short circuit upon inspection, the side wiring 120 may be connected to the first and second pads 111 and 112 of the channel to replace the through wiring 113a.

One end of the side wiring 120 is connected to a first pad 111a of the damaged channel 110a and the other end of the side wiring 120 is connected to a second pad 112a of the damaged channel 110a, thus electrically connecting the damaged channel 110a.

The side wirings 120 are formed on the side of the multilayered circuit board, and can be formed on all the sides of the multilayered circuit board.

In addition, the number of side wirings 120 formed on one side is not limited and may be selected within a proper range.

Significantly, the side wirings 120 is made of a material with a low specific resistance in order to minimize a difference in electrical characteristics when the damaged channel transfers a signal through the side wirings 120.

In the present exemplary embodiment, the material of the side wirings 120 is not particularly limited so long as it has a low resistance value. For example, the side wirings 120 may be made of copper, gold, tungsten, silver, or alloys thereof.

Accordingly, an additional resistance value through the side wirings 120 can be about 0.01 ohm or smaller, which does not substantially affect the overall resistance value.

For example, when the damaged channel is connected through the side wiring 120, a line resistance value applied to the first and second pads 111a and 112a of the damaged channel 110a is preferably within the range of 0.1 ohm to 0.5 ohm.

The range of the line resistance value may be set depending on a maximum distance and a minimum distance between the side wiring 120 and the damaged channel 110a.

FIG. 3 is a sectional view showing the state of the damaged channel 120a connected with the side wiring 120. With reference to FIG. 3, the damaged channel 110a is repaired by the nearest side wiring 120 among side wirings.

In this case, the side wiring 120 may include a first conductive line 121 formed on the side of the multilayered circuit board, a second conductive layer 122 connecting the first conductive line 121 and the first pad 111a formed on the first face of the multilayered circuit board, and a third conductive line 123 connecting the first conductive line 121 and the second pad 112a formed on the second face of the multilayered circuit board. In this case, preferably, the second conductive line 122 and the third conductive line 123 are connected with the first pad 111a and the second pad 112a, respectively, such that they form the shortest distance.

Accordingly, the damaged channel 110a with the short-circuited through wiring 130a, among the plurality of channels 110, can be repaired.

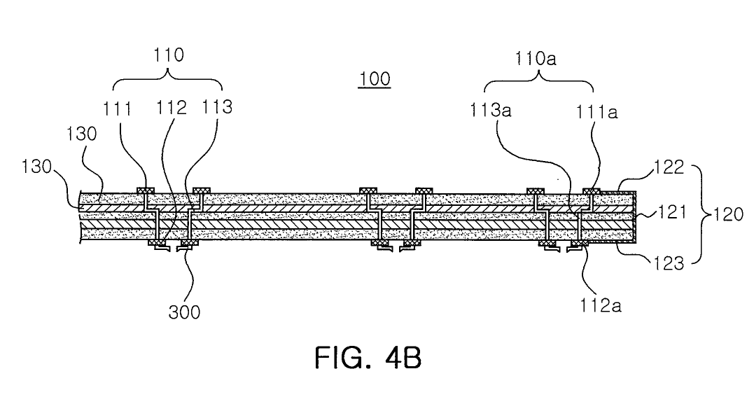

FIGS. 4a and 4b are sectional views for explaining a method for repairing a damaged channel by the space transformer according to an exemplary embodiment of the present invention.

First, as shown in FIG. 4a, the multilayered circuit board having the first and second faces which face each other and a plurality of side faces connecting the first and second faces is prepared. Next, the plurality of channels 110 having the first pad 111, the second pad 112, and the through wiring 113 are formed. Specifically, the first pad 111, to which an electrical signal is applied, is formed on the first face of the multilayered circuit board 130. The second pad 112, to which the probe 300 is connected, is formed on the second face 112. The through wirings 113 are formed to penetrate the multilayered circuit board and connect the first and second pads 111 and 112.

The method for forming the through wirings 113 is not particularly limited, and the through wirings 113 may be formed in a stacking process of the multilayered circuit board.

Thereafter, the side wiring 120 is formed on the side of the multilayered circuit board. First, the first conductive line 121 forming the side wiring 120 is formed on the side of the multilayered circuit board.

In this case, the first conductive line 121 may be formed after multilayered circuit board having the plurality of channels is fired. However, the present invention is not limited thereto and the multilayered circuit board can be fired after the formation of the first conductive line 121.

Next, when firing of the multilayered circuit board including the plurality of channels 110 is completed, the multilayered circuit board is inspected to check whether or not it has a damaged channel.

As shown in FIG. 4b, if there is a damaged channel 110a among the plurality of channels 110, the second and third conductive lines 122 and 123 are formed from the first conductive line 121 nearest to the first and second pads 111a and 112a of the damaged channel 110a.

The first, second, and third conductive lines may be selectively formed by performing screen printing, thin film sputtering, aerosol deposition, and the like, on a metal with a low specific resistance such as copper, gold, tungsten, etc.

In this manner, when one channel 110a of the plurality of channels 110 is damaged and fails to perform a normal signal transmission, the side wiring 120 can be used, whereby the space transformer 100 does not need to be discarded.

Namely, when the first and second pads 111a and 112a of the damaged channel 110a are connected by the side wiring, 120, an electrical signal can be provided to the probe 300 through the first pad 111a of the damaged channel 110a, the second conductive line 122, the first conductive line 121, the third conductive line 123, and the second pad 112b of the damaged channel 110a. Thus, the waste of the space transformer can be avoided.

As set forth above, the space transformer according to exemplary embodiments of the invention includes the side wirings formed on the side of the multilayered circuit board. Thus, when a portion of channels transferring an electrical signal to probes is damaged, the damaged channel can be repaired by means of the side wirings.

When a channel is damaged during the fabrication process of the space transformer or when a channel is aged according to the use of the probe card, the channel can be repaired, so unnecessary replacement cost can be reduced.

While the present invention has been shown and described in connection with the exemplary embodiments, it will be apparent to those skilled in the art that modifications and variations can be made without departing from the spirit and scope of the invention as defined by the appended claims.

What is claimed is:

1. A space transformer for a probe card, the space transformer comprising:
a multilayered circuit board having first and second faces which face each other and a plurality of side faces connecting the first and second faces;
a plurality of channels including a first pad formed on the first face and receiving an electrical signal applied from the exterior, a second pad formed on the second face, to which a probe is connected, and a through wiring penetrating the multilayered circuit board and connecting the first and second pads; and
side wirings formed on the side faces and connecting first and second pads of a damaged channel among a plurality of channels.

2. The space transformer of claim 1, wherein the side wirings are formed on every side faces of the multilayered circuit board.

3. The space transformer of claim 1, wherein the damaged channel is connected by a side wiring formed to be nearest among the side wirings.

4. The space transformer of claim 1, wherein the side wirings comprise a first conductive line formed on the side of the multilayered circuit board, a second conductive line connecting the first conductive line and the first pad, and a third conductive line connecting the first conductive line and the second pad.

5. The space transformer of claim 4, wherein the second and third conductive lines are formed at the shortest distance.

6. The space transformer of claim 1, wherein the side wirings are made of one selected from the group consisting of copper, gold, tungsten, sliver, and alloys thereof.

7. A method of repairing a space transformer for a probe card, the method comprising:
preparing a multilayered circuit board having first and second faces which face each other and a plurality of side faces connecting the first and second faces;
forming a plurality of channels including a first pad formed on the first face and receiving an electrical signal applied from the exterior, a second pad formed on the second face, to which a probe is connected, and a through wiring penetrating the multilayered circuit board and connecting the first and second pads; and
forming side wirings on the side faces to connect first and second pads of a damaged channel among a plurality of channels.

8. The method of claim 7, wherein the side wirings comprise a first conductive line formed on the side of the multilayered circuit board, a second conductive line connecting the first conductive line and the first pad of the damaged channel, and a third conductive line connecting the first conductive line and the second pad of the damaged channel, wherein the first conductive line is fired along with the multilayered circuit board.

9. The method of claim 8, wherein the first conductive line, the second conductive line, and the third conductive line are formed after the multilayered circuit board is fired.

10. The method of claim 8, wherein the first conductive line, the second conductive line, and the third conductive line are formed through screen printing, thin film sputtering, or aerosol deposition.
